(19) United States
(12) Patent Application Publication
(10) Pub. No.: US 2008/0122464 A1
(43) Pub. Date: May 29, 2008

(54) Replaceable probe

(75) Inventors: Yu-Min Cheng, Taipei County (TW); Wen-Ying Cheng, Taipei County (TW); Min-Hsiang Sung, Kaohsiung County (TW)

Correspondence Address: BIRCH STEWART KOLASCH & BIRCH, PO BOX 747, FALLS CHURCH, VA, 22040-0747, US

(73) Assignee: C.C.P. CONTACT PROBES CO., LTD.

(21) Appl. No.: 11/506,841

(22) Filed: Aug. 21, 2006

(51) Int. Cl. G01R 1/067

(52) U.S. Cl. 324/754

(57) ABSTRACT

A replaceable probe to be used on a test feature includes a hollow probe body to house an elastic element and at least one needle inserting in the probe body. The needle presses the elastic element and is retractable in the probe body. The probe body is surrounded by a hollow sleeve to form an anchoring relationship with the inner wall of the sleeve. The sleeve has an opening on one end to receive the needle and an open side on other end to allow the probe body to escape the sleeve. Thus when the needle is worn out after being used for a period of time, the probe body can be removed from the sleeve and test feature for replacement without disassembling the test feature. Replacement can be done quickly.

### FIELD OF THE INVENTION

The present invention relates to a test probe and particularly to a replaceable test probe that has an anchoring sleeve on the periphery of a probe body.

### BACKGROUND OF THE INVENTION

Probes are commonly used for testing finished electronic elements and circuit boards. A probe is mounted onto a test feature to be in contact with an electronic element or circuit board to send test results through a conductive wire to a computer to detect whether defects exist on a testing object.

R.O.C. patent No. M271159 entitled “Improved test feature” discloses a probe and a test feature. It mainly includes a base on the test feature that has a needle panel, a clipping plate, a top plate and a plurality of probes mounted thereon. The needle panel has needle openings corresponding to testing spots of a testing object (such as printed circuit board). The probes include a probe body, a spring and a needle. The probe body is inserted into the needle opening, and has a conductive wire on one end to transmit signals to a computer. The spring provides an extensible force to give the needle an elastic returning force in the probe body. Hence the probe can be anchored on the needle panel. The clipping plate and top plate have respectively apertures corresponding to the needle openings of the needle panel. The needles run through the apertures of the clipping plate and top plate, and extended outside the top plate. The testing object is located above the top plate. A test machine moves the test spots of the testing object in contact with the needles. Electric signals are transmitted through the conductive wire connecting to the probe body to the test machine to finish test operation.

After the probe has been used for testing and operation for a period of time, the needle tends to be worn out. The entire probe has to be replaced. The base of the test feature has to be disassembled to do replacement. After disassembly of the test feature, technicians have to find out damage locations of the probe to replace and anchor the entire probe. Then the test feature has to be assembled again. Such a replacement process for the probe is tedious and time-consuming. Disassembly and assembly of the teat feature are especially troublesome. It lowers the total efficiency of test operation.

### SUMMARY OF THE INVENTION

It is an object of the present invention to provide a replaceable probe that can be replaced quickly. In the event that a probe body is damaged, it can be removed from a test feature without disassembling the test feature. Therefore replacement of the probe body can be done rapidly.

To achieve the foregoing object, the invention includes a hollow probe body, an elastic element located in the probe body, and at least one needle inserting into the probe body. The needle presses the elastic element and is retractable in the probe body. The probe body is surrounded by a hollow sleeve which has an inner wall to form an anchoring relationship with the probe body. The sleeve has an opening on one end to receive the needle and an open side on other end to allow the probe to escape the sleeve. The probe body is anchored in a test feature through the sleeve, and can be removed from the sleeve to be replaced rapidly.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a perspective view of an embodiment of the invention.

FIG. 2 is an exploded view of an embodiment of the invention.

FIG. 3 is a sectional view of an embodiment of the invention.

FIGS. 4A and 4B are sectional views of the invention in use conditions.

### DETAILED DESCRIPTION OF THE PREFERRED EMBODIMENT

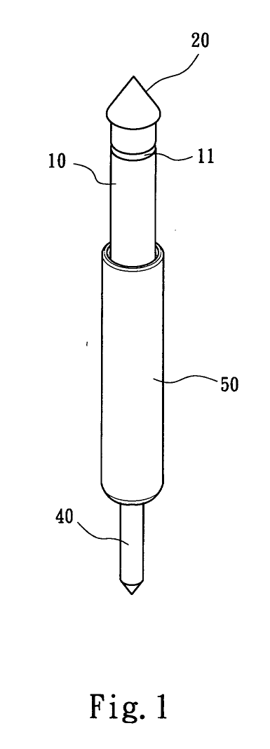

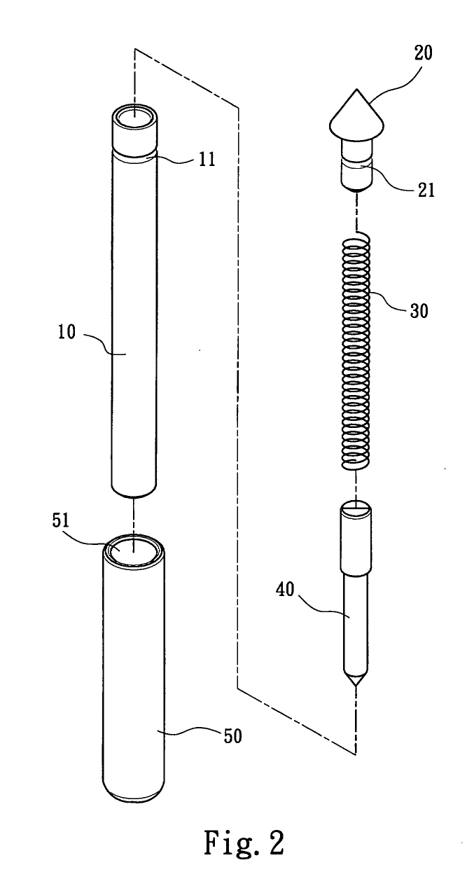

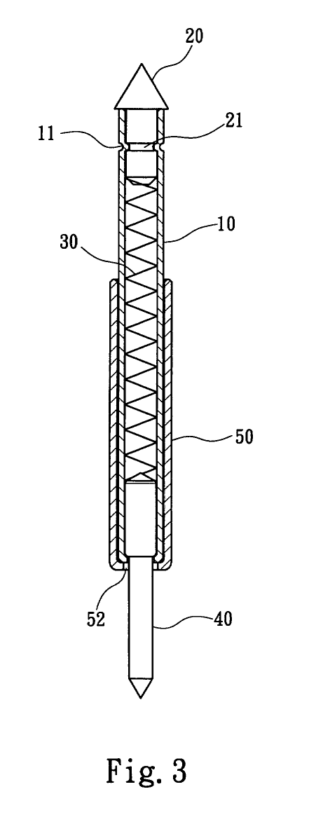

Please refer to FIG. 1 for an embodiment of the invention. The replaceable probe according to the invention includes a hollow probe body 10 which has one end holding an anchor strut 20. The probe body 10 and the anchor strut 20 have respectively an anchor groove 11 and 21 corresponding to each other to form an anchoring relationship. The hollow probe body 10 houses an elastic element 30 (referring to FIG. 2). The probe body 10 has other end to receive a needle 40 which presses the elastic element 30. The needle 40 is retractable in the probe body 10 because of the elastic force of the elastic element 30. The probe body 10 further is surrounded by a hollow sleeve 50 which has an inner wall to form an anchoring relationship with the probe body 10. The sleeve 50 has an opening 52 on one end (referring to FIG. 3) that has a diameter smaller than the outer diameter of the probe body 10, and an open side 51 on other end to allow the probe body 10 to escape the sleeve 50.

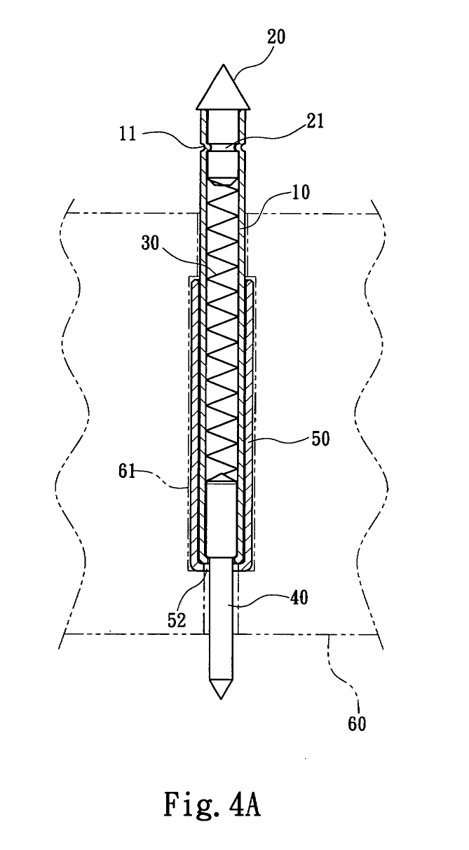

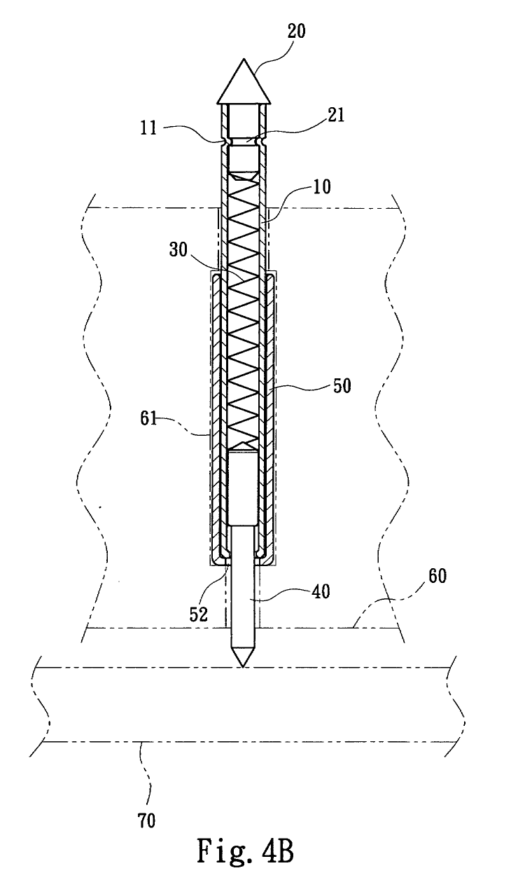

Referring to FIG. 4A, when in use, the invention is disposed in a test feature 60 which has a confining zone 61 to harness sleeve 50 from escaping the test feature 60. The probe body 10 runs through the sleeve 50 with the needle 40 exposing outside the test feature 60 to perform test. The needle 40 is pressed on a testing object 70 (referring to FIG. 4B) to compress the elastic element 30 inwards. The inner wall of the sleeve 50 and the probe body 10 form an anchoring relationship by a forced coupling. Hence the probe body 10 does not escape the sleeve 50 under the action force during testing. Test on the testing object 70 can be done smoothly. After a number of tests and the needle 10 is worn out and has to be replaced, the probe body 10 can be removed forcefully from the sleeve 50 and the test feature by grasping the exposed portion outside the test feature 60 to release the anchoring relationship between the inner wall of the sleeve 50 and the probe body 10. Then a new probe body 10 (along the needle 40) can be inserted into the sleeve 50 held in the test feature 60 to complete replacement. The invention allows the probe body 10 to be removed from the test feature 60 for replacement without disassembling the test feature 60. Replacement can be done rapidly.

While the preferred embodiment of the invention has been set forth for the purpose of disclosure, modifications of the disclosed embodiment of the invention as well as other embodiments thereof may occur to those skilled in the art. Accordingly, the appended claims are intended to cover all embodiments which do not depart from the spirit and scope of the invention.

What is claimed is:

1. A replaceable probe, comprising:
a hollow probe body housing an elastic element;
at least one needle which has one end inserting into the probe body to press the elastic element and is retractable in the probe body; and
a hollow sleeve surrounding the probe body and having an inner wall to form an anchoring relationship with the probe body, and having an opening on one end to receive the needle and an open side on other end to receive the probe body and allow the probe body to escape the sleeve.

2. The replaceable probe of claim 1, wherein the sleeve is located and confined in a test feature, the probe body being allowed to escape the sleeve and the test feature by releasing the anchoring relationship between the probe body and the sleeve.

3. The replaceable probe of claim 1, wherein the opening is formed at a diameter smaller than the outer diameter of the probe body.
